(19) United States
(12) Patent Application Publication
(10) Pub. No.: US 2020/0006272 A1
(43) Pub. Date: Jan. 2, 2020

(54) THROUGH-SILICON VIA PILLARS FOR CONNECTING DICE AND METHODS OF ASSEMBLING SAME

(71) Applicants: Andreas Augustin, Munich (DE); Georg Seidemann, Landshut (DE); Thomas Wagner, Regelsbach (DE); Bernd Waidhas, Pettendorf (DE)

(72) Inventors: Andreas Augustin, Munich (DE); Georg Seidemann, Landshut (DE); Thomas Wagner, Regelsbach (DE); Bernd Waidhas, Pettendorf (DE)

(21) Appl. No.: 16/024,413

(22) Filed: Jun. 29, 2018

(51) Int. Cl. H01L 23/00; H01L 23/538; H01L 23/498; H01L 21/768

(52) U.S. Cl. CPC H01L 24/14; H01L 24/17; H01L 23/5384; H01L 21/76877; H01L 21/76802; H01L 21/76898; H01L 23/49816

(57) ABSTRACT

Reduced-profile semiconductor device apparatus are achieved by thinning a semiconductive device substrate at a backside surface to expose a through-silicon via pillar, forming a recess to further expose the through-silicon via pillar, and by seating an electrical bump in the recess to contact both the through-silicon via pillar and the recess. In an embodiment, the electrical bump contacts a semiconductor package substrate to form a low-profile semiconductor device apparatus. In an embodiment, the electrical bump contacts a subsequent die to form a low-profile semiconductor device apparatus.

### FIELD

This disclosure relates to through-silicon via pillars that are used to connect between semiconductive dice, and semiconductor device packages that use the through-silicon via pillars for a semiconductor apparatus.

### BACKGROUND

Semiconductive device miniaturization during packaging includes challenges to control package thickness while improving interconnection quality for multi-die packaging architectures.

### BRIEF DESCRIPTION OF THE DRAWINGS

Disclosed embodiments are illustrated by way of example, and not by way of limitation, in the figures of the accompanying drawings where like reference numerals may refer to similar elements, in which:

FIG. 1A is a cross-section elevation of a semiconductive device during processing according to an embodiment:

FIG. 1B is a cross-section elevation of the semiconductive device depicted in FIG. 1A after further processing according to an embodiment,

FIG. 1C is a cross-section elevation of the semiconductive device depicted in FIG. 1B after further processing according to an embodiment:

FIG. 1D is a cross-section elevation of the semiconductive device depicted in FIG. 1B after further processing according to an embodiment;

FIG. 1E is a cross-section elevation of the semiconductive device depicted in FIG. 1D after further processing according to an embodiment;

FIG. 1 is a cross-section elevation of the semiconductive device depicted in FIG. 1D after further processing according to an embodiment:

FIG. 1x is a cross-section composite of a semiconductor apparatus according to several embodiments;

FIG. 2 is a cross-section elevation of a semiconductor apparatus according to an embodiment;

FIG. 3 is a cross-section elevation of a semiconductor apparatus according to an embodiment:

FIG. 4 is a cross-section elevation of a semiconductor apparatus according to an embodiment;

FIG. 5 is a cross-section elevation of a semiconductive apparatus according to an embodiment;

FIG. 6 is a cross-section elevation of a semiconductive apparatus according to an embodiment;

FIG. 7 is a cross-section elevation of a semiconductive apparatus according to an embodiment;

FIG. 8 is a top plan of a portion of the semiconductor apparatus depicted in FIG. 7 according to an embodiment;

FIG. 9 is a process flow diagram 900 according to an embodiment; and

FIG. 10 is included to show an example of a higher-level device application for the disclosed embodiments.

### DETAILED DESCRIPTION

Reduced-profile semiconductor device apparatus are achieved by thinning a semiconductive die substrate at a backside surface to expose a through-silicon via pillar, forming a recess to further expose the through-silicon via pillar, and by seating an electrical bump in the recess to contact both the through silicon via (TSV) pillar and the recess. Although the semiconductive die substrate embodiments include TSV pillars, it is understood that the semiconductive die substrate may be other semiconductive materials including, e.g., III-V semiconductive materials.

In an embodiment, the electrical bump contacts a semiconductor package substrate to form a low-profile semiconductor device apparatus. In an embodiment, the electrical bump contacts a subsequent die to form a low-profile semiconductor device apparatus.

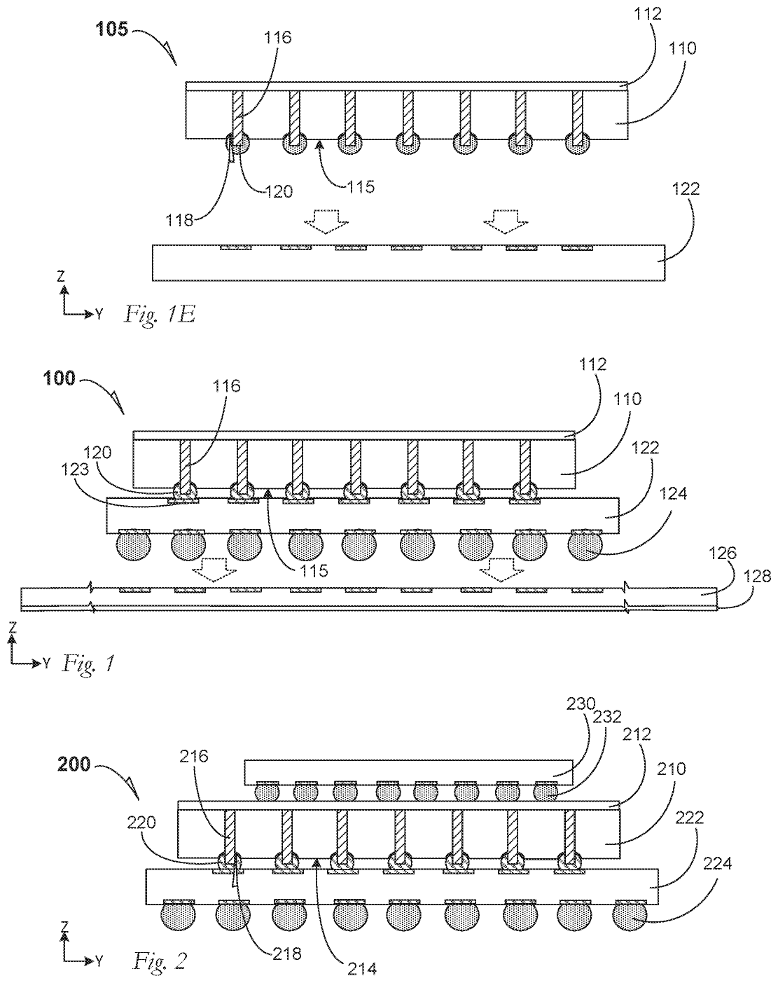

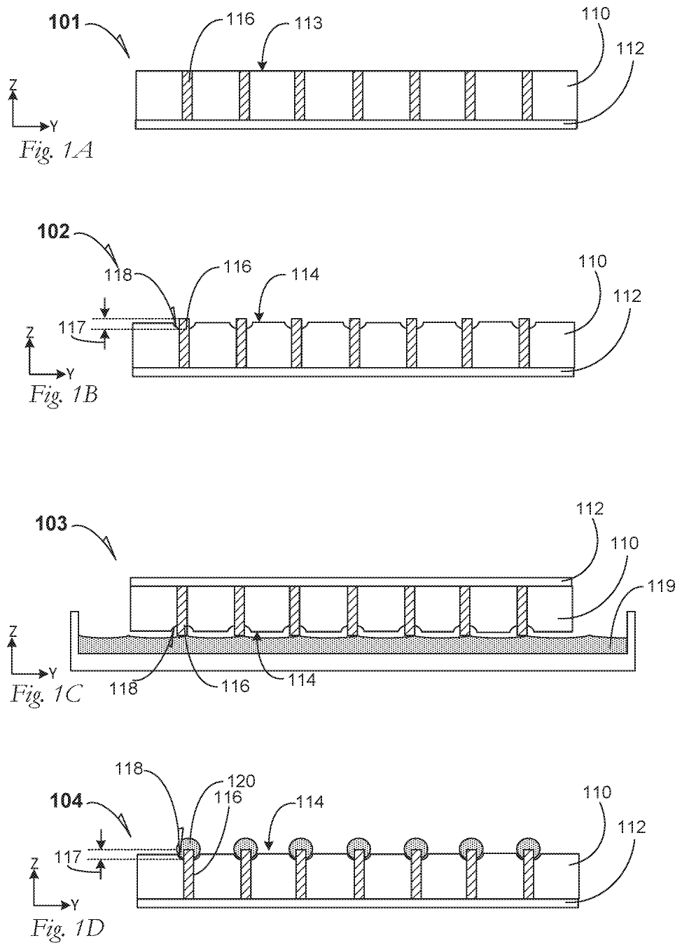

FIG. 1A is a cross-section elevation of a semiconductive device 101 during processing according to an embodiment. A semiconductive device substrate 110 includes an active surface 112 and a backside surface 113. The active surface 112 includes active devices that have been processed in the semiconductive die substrate 110 such as transistors, and the active surface 112 also includes metallization that connects to the active devices. The semiconductive device backside surface 113 is a bare semiconductive surface that is opposite the active surface 112.

A through-silicon via (TSV) pillar 116 communicates from the active surface 112 to the backside surface 113, and it is formed by any useful TSV-forming technique.

FIG. 1B is a cross-section elevation of the semiconductive device 101 depicted in FIG. 1A after further processing according to an embodiment. The semiconductive device 102 has been processed at the backside surface 113, depicted in FIG. 1A, to form a processed backside surface 114 that includes a recess 118 in the semiconductive device substrate 110 at the processed backside surface 114.

As illustrated, the TSV pillar 116 emerges within the recess 118 after etching to reduce the height (Z-direction) of the backside surface 113 to achieve the processed backside surface 114. Height reduction is accomplished in an embodiment by a wet etch to achieve the processed backside surface 114, followed by a directional etch to achieve the recess 118.

In an example embodiment, the recess 118 is first etched by patterning a mask (not pictured) on the backside surface 113 where the several TSV pillars 116 are centered upon opens in the mask. The directional etch is selective to leaving the several TSV pillars 116, and the recess 118 forms a depth 117 measured from the end of the TSV pillars 116. Thereafter, the isotropic etch is carried out that is also selective to leaving the TSV pillars 116 while lowering the backside surface 113 to achieve the processed backside surface 114.

As illustrated in an embodiment, the processed backside surface 114 has been lowered to allow the TSV pillar 116 to extend beyond (Z-direction) the processed backside surface 114. In an embodiment, wet etching is first done to achieve the processed backside surface 114, followed by directional etching to form the recess 118. In any event, each etch process exposes the TSV pillar 116 to increase prominence compared to the semiconductive material of the semiconductive device substrate 110.

FIG. 1C is a cross-section elevation of the semiconductive device 102 depicted in FIG. 1B after further processing according to an embodiment. The semiconductive device 103 has been processed by inverting the semiconductive device substrate 110 and dipping the several TSV pillars 116 exposed from the processed backside surface 114 of the semiconductive device substrate 110 into molten solder 119. Dipping is done sufficiently that molten solder 119 wets and adheres to the several TSV pillars 116 including filling the recesses 118. In an embodiment, the molten solder 119 includes chemistry that preferentially wets the TSV pillar 116 more than the semiconductive material of the semiconductive device substrate 110 within the recess 118. In any event, the molten solder 119 is both seated within the recess 118 and adheres to the TSV pillar 116.

FIG. 1D is a cross-section elevation of the semiconductive device 102 depicted in FIG. 1B after further processing according to an embodiment. The semiconductive device 104 has been re-inverted as the TSV pillar 116 has acquired an electrical bump 120 that is seated in the recess 118 as well as the electrical bump 120 is in contact with the TSV pillar 116. In an embodiment, the recess depth 117 is measured from the end of the TSV pillar 116 to the bottom of the recess 118. In an embodiment, the electrical bump 120 vertically protrudes by half or more above the processed backside surface 114 (see FIG. 1x). In an embodiment, the electrical bump 120 vertically protrudes by one-half or less above the processed backside surface 114. In an embodiment, the electrical bump 120 vertically protrudes by one-third or less above the processed backside surface 114.

FIG. 1E is a cross-section elevation of the semiconductive device 103 depicted in FIG. 1D after further processing according to an embodiment. The semiconductive device 105 has processed by inverting the semiconductive device substrate 110, and directional arrows indicate movement of the semiconductive device substrate 110 toward a semiconductor package substrate 122 to make contact with the electrical bump 116.

FIG. 1 is a cross-section elevation of the semiconductive device 104 depicted in FIG. 1D after further processing according to an embodiment. The semiconductor apparatus 100 has been seated onto the semiconductor package substrate 122 and the electrical bump 120 depicted in FIG. 1D has been reflowed into an electrical bump 120 to contact both the TSV pillar 116 and the semiconductor package substrate 122 at a package-substrate bond pad 123. In an embodiment, the end of the TSV pillar 116 as well as the electrical bump 121 contact the semiconductor package substrate 122 (see FIG. 1x).

In a system embodiment, the semiconductive apparatus 100 including the semiconductor package substrate 122, is assembled to a board 126 such as a motherboard in a computing system. In an embodiment, the board 126 includes a shell 128 that provides at least one of physical and electrical-insulation protection to the semiconductive apparatus 100. In an embodiment, the shell 128 is the outer shell of a hand-held computing system such as a wireless communicator.

FIG. 1x is a cross-section composite of a semiconductor apparatus 100x according to several embodiments. In an embodiment, a TSV pillar 116x also contacts the package substrate 122x at a package-substrate bond pad 123x.

In an embodiment where an electrical bump 120x contacts an extended exposed length of the TSV pillar 116x within a recess 118, and the package-substrate bond pad 123x. In an embodiment, the electrical bump 120x shows a convex exposed contour between the semiconductive device substrate 110x and the semiconductor package substrate 122x as it has been reflowed to wet both the TSV pillar 116x and the package-substrate bond pad 123x.

By contrast where a TSV pillar 116 does not also contact the package substrate 122x at a package-substrate bond pad 123, an electrical bump 120 maintains a concave contour as it has been reflowed to wet both the TSV pillar 116 and a package-substrate bond pad 123.

FIG. 2 is a cross-section elevation of a semiconductor apparatus 200 according to an embodiment. A semiconductive device substrate 210 has been processed similarly to the semiconductive device substrate 110 embodiments depicted in FIGS. 1A through 1D. The semiconductive device substrate 210 may also be referred to as a first die 210. As illustrated, an active surface 112 and a processed backside surface 214 are on opposite surfaces of the first die 210. The processed backside surface 214 includes a recess 218 into which a first electrical bump 220 has been seated and reflowed. The first electrical bump 220 is also in contact with a TSV pillar 216. As illustrated a semiconductor package substrate 222 is in contact with the first electrical bump 220. In an embodiment, the end of the TSV pillar 216 as well as the electrical bump 220 contact the semiconductor package substrate 122. A land-side electrical bump 224 is configured to bond with further structures such as with a board such as the board 126 depicted in FIG. 1.

In an embodiment, a subsequent die 230 is in contact with the active surface 212 by a subsequent electrical bump 232.

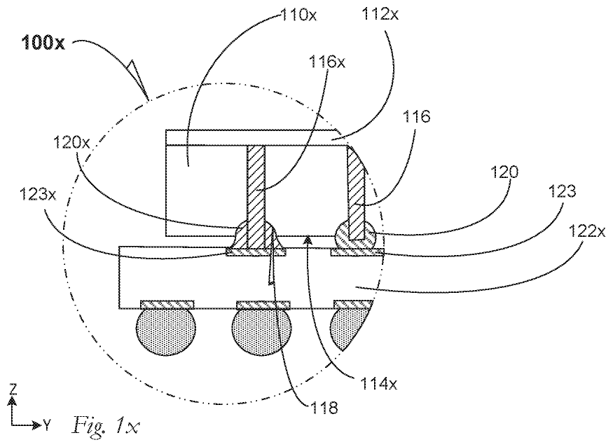

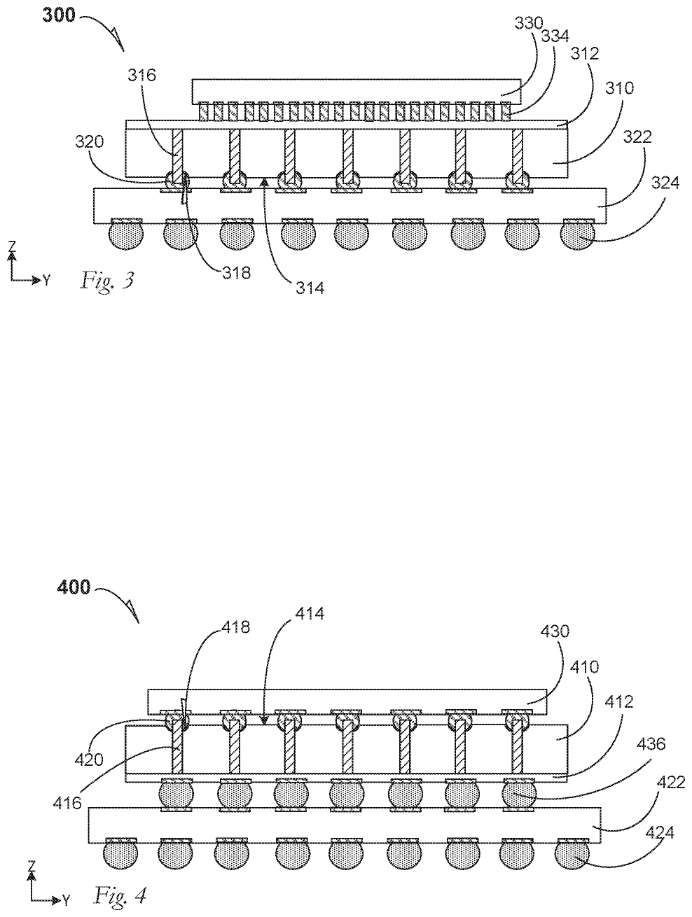

FIG. 3 is a cross-section elevation of a semiconductor apparatus 300 according to an embodiment. A semiconductive device substrate 310 has been processed similarly to the semiconductive device substrates 110 and 210 embodiments depicted in FIGS. 1A through 1D and FIG. 2. The semiconductive device substrate 310 may also be referred to as a first die 310. As illustrated, an active surface 312 and a processed backside surface 314 are on opposite surfaces of the first die 310. The processed backside surface 314 includes a recess 318 into which an electrical bump 320 has been seated and reflowed. The electrical bump 320 is also in contact with a TSV pillar 316. As illustrated a semiconductor package substrate 322 is in contact with the electrical bump 320. In an embodiment, the end of the TSV pillar 316 as well as the electrical bump 320 contact the semiconductor package substrate 322 (see, e.g., FIG. 1x).

In an embodiment, a contact pillar 334 contacts the active surface 312 and a subsequent die 330. As illustrated, the semiconductor apparatus 300 has a lower profile by seating the electrical bump 320 in the recess 318.

FIG. 4 is a cross-section elevation of a semiconductor apparatus 400 according to an embodiment. A semiconductive device substrate 410 has been processed similarly to the semiconductive die substrates 110, 210 and 310 embodiments depicted in FIGS. 1A through 1D, FIG. 2 and FIG. 3. The semiconductive device substrate 410 may also be referred to as a first die 410.

As illustrated, an active surface 412 and a processed backside surface 414 are on opposite surfaces of the first die 410. The processed backside surface 414 includes a recess 418 into which a first electrical bump 420 has been seated and reflowed. The first electrical bump 420 is also in contact with a TSV pillar 416. As illustrated, the first electrical bump 420 contacts both the TSV pillar 416 and a subsequent semiconductive device 430. In an embodiment, the end of the TSV pillar 416 as well as the first electrical bump 420 contact the subsequent semiconductive device 430 (see, e.g. FIG. 1x).

In an embodiment, a second electrical bump 436 contacts the active surface 412. In an embodiment, the second electrical bump 436 contacts both the active surface 412 and a semiconductor package substrate 422. In an embodiment, the semiconductor package substrate 422 is outfitted with a ball-grid array 424 for further connection to a board such as the board 126 depicted in FIG. 1.

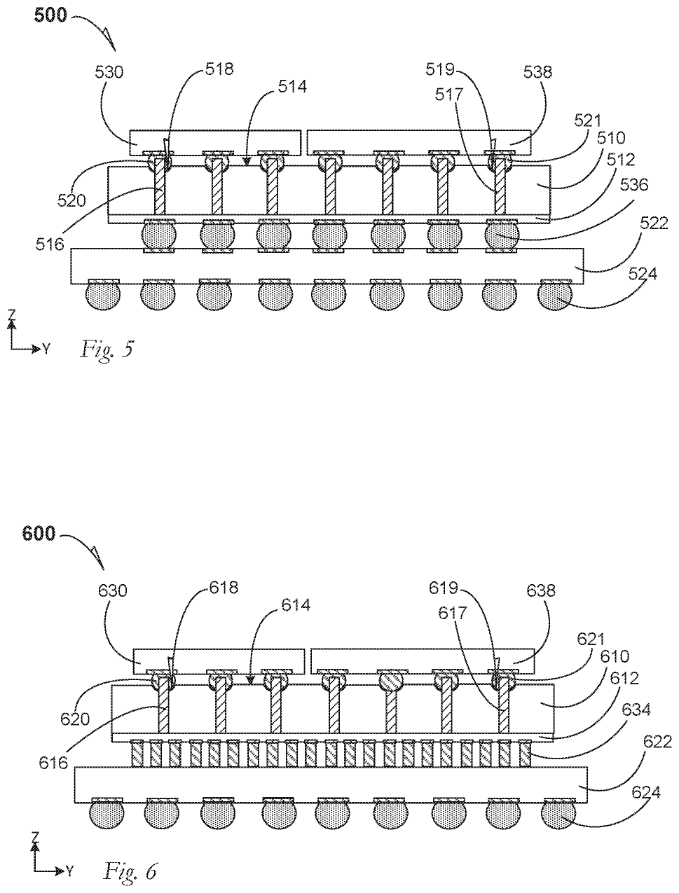

FIG. 5 is a cross-section elevation of a semiconductor apparatus 500 according to an embodiment. A semiconductive device substrate 510 has been processed similarly to the semiconductive device substrates 110, 210, 310 and 410 embodiments depicted in FIGS. 1A through 1D, FIG. 2, FIG. 3 and FIG. 4. The semiconductive device substrate 510 may also be referred to as a first die 510.

As illustrated, an active surface 512 and a processed backside surface 514 are on opposite surfaces of the first die 510. The processed backside surface 514 includes a recess 518 into which a first electrical bump 520 has been seated and reflowed. The first electrical bump 520 is also in contact with a first TSV pillar 516. As illustrated, the first electrical bump 520 contacts both the first TSV pillar 516 and a subsequent semiconductive device 530. In an embodiment, the end of the first TSV pillar 516 as well as the first electrical bump 520 contact the subsequent semiconductive device 530 (see, e.g. Figure x).

In an embodiment, a second semiconductive device 538 is coupled to the first die 510 by a second electrical bump 521. The second electrical bump 521 has been formed onto a second TSV pillar 517, and that is seated in a second recess 519 in the first die 510. The second TSV pillar 517 communicates from the active surface 512 to the processed backside surface 514 and it emerges from the second recess 519.

In an embodiment, the first TSV pillar 516 also contacts the subsequent semiconductive device 530 along with the first electrical bump 520. In an embodiment, the second TSV pillar 517 also contacts the second semiconductive device 538 along with the second electrical bump 521.

In an embodiment, a package substrate electrical bump 536 contacts the active surface 512. In an embodiment, the package substrate electrical bump 536 contacts both the active surface 512 and a semiconductor package substrate 522. In an embodiment, the semiconductor package substrate 522 is outfitted with a ball-grid array 524 for further connection to a board such as the board 126 depicted in FIG. 1.

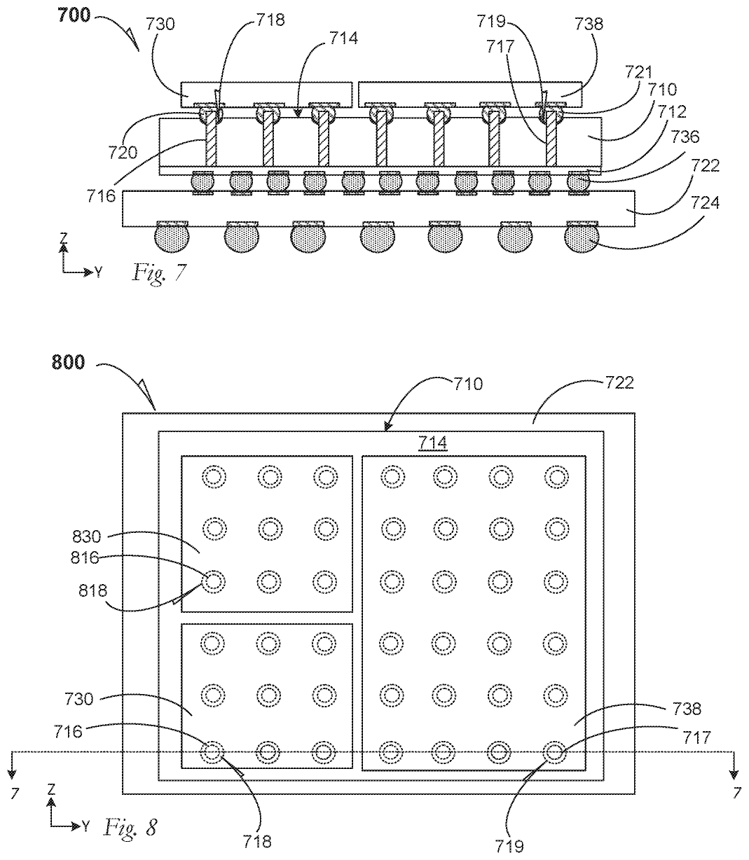

FIG. 6 is a cross-section elevation of a semiconductor apparatus 600 according to an embodiment. A semiconductive device substrate 610 has been processed similarly to the semiconductive device substrates 110, 210, 310, 410 and 510 embodiments depicted in FIGS. 1A through 1D, FIG. 2, FIG. 3, FIG. 4 and FIG. 5. The semiconductive device substrate 610 may also be referred to as a first die 610.

As illustrated, an active surface 612 and a processed backside surface 614 are on opposite surfaces of the first die 610. The processed backside surface 614 includes a first recess 618 into which a first electrical bump 620 has been seated and reflowed. The first electrical bump 620 is also in contact with a first TSV pillar 616. As illustrated, the first electrical bump 620 contacts both the first TSV pillar 616 and a subsequent semiconductive device 630. In an embodiment, the end of the first TSV pillar 616 as well as the first electrical bump 620 contact the subsequent semiconductive device 630.

In an embodiment, a second semiconductive device 638 is coupled to the first semiconductive device 610 by a second electrical bump 621. The second electrical bump 621 has been formed onto a second TSV pillar 617, and that is seated in a second recess 619 in the first die 610. The second TSV pillar 617 communicates from the active surface 612 to the processed backside surface 614 and it emerges from the second recess 619.

In an embodiment, the first TSV pillar 616 also contacts the subsequent semiconductive device 630 along with the first electrical bump 620. In an embodiment, the second TSV pillar 617 also contacts the second semiconductive device 638 along with the second electrical bump 621.

In an embodiment, a package substrate contact pillar 636 contacts the active surface 612 of the first die 610 and a semiconductor package substrate 622. In an embodiment, the semiconductor package substrate 622 is outfitted with a ball-grid array 624 for further connection to a board such as the board 126 depicted in FIG. 1.

FIG. 7 is a cross-section elevation of a semiconductor apparatus 700 according to an embodiment. A semiconductive device substrate 710 has been processed similarly to the semiconductive device substrates 110, 210, 310, 410, 510 and 610 embodiments depicted in FIGS. 1A through 1D, FIG. 2, FIG. 3, FIG. 4. FIG. 5 and FIG. 6. The semiconductive device substrate 710 may also be referred to as a first die 710.

As illustrated, an active surface 712 and a processed backside surface 714 are on opposite surfaces of the first die 710. The processed backside surface 714 includes a first recess 718 into which a first electrical bump 720 has been seated and reflowed. The first electrical bump 720 is also in contact with a first TSV pillar 716. As illustrated, the first electrical bump 720 contacts both the first TSV pillar 716 and a subsequent semiconductive device 730. In an embodiment, the end of the first TSV pillar 716 as well as the first electrical bump 720 contact the subsequent semiconductive device 730.

In an embodiment, a second semiconductive device 738 is coupled to the first semiconductive device 710 by a second electrical bump 721. The second electrical bump 721 has been formed onto a second TSV pillar 717, and the second electrical bump 721 is seated in a second recess 719 in the first die 710.

The second TSV pillar 717 communicates from the active surface 712 to the processed backside surface 714 and it emerges from the second recess 719.

In an embodiment, the first TSV pillar 716 also contacts the subsequent semiconductive device 730 along with the first electrical bump 720. In an embodiment, the second TSV pillar 717 also contacts the second semiconductive device 738 along with the second electrical bump 721.

In an embodiment, a package substrate electrical bump 736 contacts the active surface 712. In an embodiment, the package substrate electrical bump 736 contacts both the active surface 712 and a semiconductor package substrate 722. In an embodiment, the semiconductor package substrate 722 is outfitted with a ball-grid array 724 for further connection to a board such as the board 126 depicted in FIG. 1.

FIG. 8 is a top plan 800 of a portion of the semiconductor apparatus 700 depicted in FIG. 7 according to an embodiment. The top plan 800 illustrates the semiconductor apparatus 700, taken along the section line 7-7 in FIG. 8.

The semiconductive device substrate 710 supports the subsequent die 730 by contact to the first TSV pillar 716 (illustrated in ghosted lines), and the first electrical bump 720 (not illustrated) contacts the subsequent semiconductive device 730 while seated in the first recess 718 (illustrated in ghosted lines).

Similarly, the semiconductive device substrate 710 supports the second semiconductive device 738 by contact to the second TSV pillar 717 (illustrated in ghosted lines), and the second electrical bump 721 (not illustrated) contacts the second semiconductive device 738 while seated in the second recess 719 (illustrated in ghosted lines). Additionally, the semiconductive device substrate 710 supports a third semiconductive device 830 by contact to a third TSV pillar 816 (illustrated in ghosted lines), and a third electrical bump (not illustrated) contacts the third semiconductive device 830 while seated in a third recess 818 (illustrated in ghosted lines).

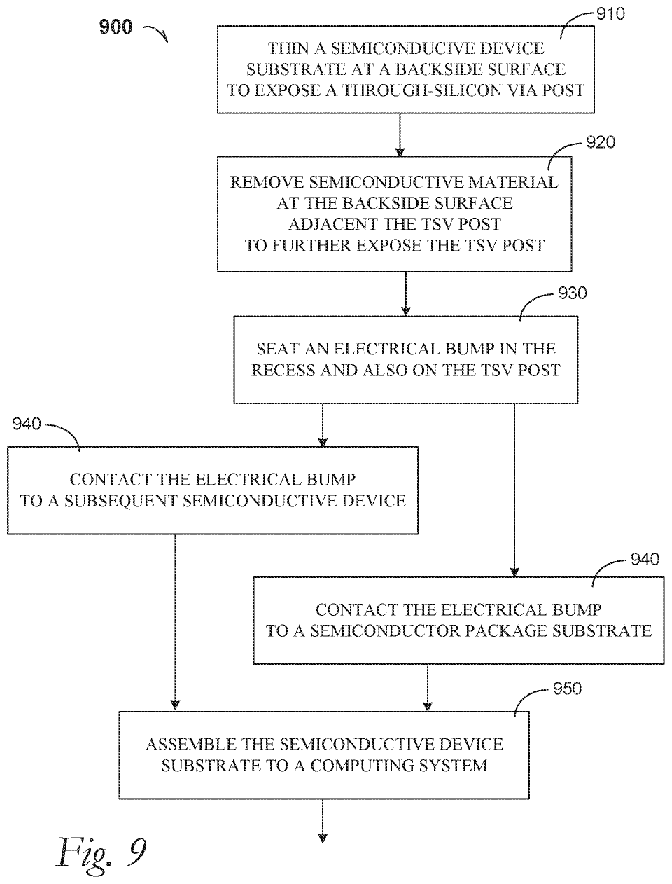

FIG. 9 is a process flow diagram 900 according to an embodiment.

At 910, the process includes thinning a semiconductive device substrate at a backside surface to expose a TSV post.

At 920, the process includes removing semiconductive material at the backside surface adjacent the TSV post to further expose the TSV post.

At 930, the process includes seating an electrical bump in the recess and also on the TSV post.

At 940, the process includes contacting the electrical bump to a subsequent semiconductive device.

At 950, the process includes contacting the electrical bump to a semiconductor package substrate.

At 960, the process includes assembling the semiconductive device substrate to a subsequent semiconductive device.

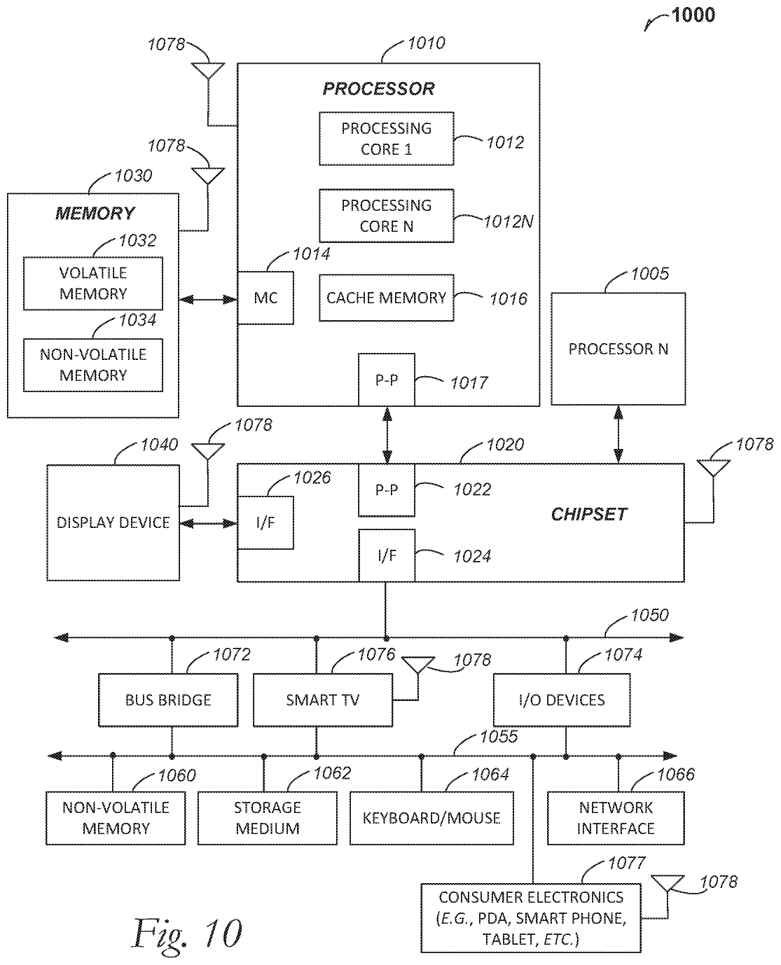

FIG. 10 is included to show an example of a higher-level device application for the disclosed embodiments. The TSV pillar and electrical bump in backside recess embodiments may be found in several parts of a computing system. In an embodiment, the TSV pillar and electrical bump in backside recess embodiments can be part of a communications apparatus such as is affixed to a cellular communications tower. In an embodiment, a computing system 1000 includes, but is not limited to, a desktop computer. In an embodiment, a system 1000 includes, but is not limited to a laptop computer. In an embodiment, a system 1000 includes, but is not limited to a tablet. In an embodiment, a system 1000 includes, but is not limited to a notebook computer.

In an embodiment, a system 1000 includes, but is not limited to a personal digital assistant (PDA). In an embodiment, a system 1000 includes, but is not limited to a server. In an embodiment, a system 1000 includes, but is not limited to a workstation. In an embodiment, a system 1000 includes, but is not limited to a cellular telephone. In an embodiment, a system 1000 includes, but is not limited to a mobile computing device. In an embodiment, a system 1000 includes, but is not limited to a smart phone. In an embodiment, a system 1000 includes, but is not limited to an internet appliance. Other types of computing devices may be configured with the microelectronic device that includes TSV pillar and electrical bump in backside recess embodiments.

In an embodiment, the processor 1010 has one or more processing cores 1012 and 1012N, where 1012N represents the Nth processor core inside processor 1010 where N is a positive integer. In an embodiment, the electronic device system 1000 using a TSV pillar and electrical bump in backside recess embodiment that includes multiple processors including 1010 and 1005, where the processor 1005 has logic similar or identical to the logic of the processor 1010. In an embodiment, the processing core 1012 includes, but is not limited to, pre-fetch logic to fetch instructions, decode logic to decode the instructions, execution logic to execute instructions and the like. In an embodiment, the processor 1010 has a cache memory 1016 to cache at least one of instructions and data for the multi-layer solder resist on a semiconductor device package substrate in the system 1000. The cache memory 1016 may be organized into a hierarchal structure including one or more levels of cache memory.

In an embodiment, the processor 1010 includes a memory controller 1014, which is operable to perform functions that enable the processor 1010 to access and communicate with memory 1030 that includes at least one of a volatile memory 1032 and a non-volatile memory 1034. In an embodiment, the processor 1010 is coupled with memory 1030 and chipset 1020. In an embodiment, the chipset 1020 is part of a TSV pillar and electrical bump in backside recess embodiment depicted in any of FIGS. 1-8. The processor 1010 may also be coupled to a wireless antenna 1078 to communicate with any device configured to at least one of transmit and receive wireless signals. In an embodiment, the wireless antenna interface 1078 operates in accordance with, but is not limited to, the IEEE 802.11 standard and its related family, Home Plug AV (HPAV), Ultra Wide Band (UWB), Bluetooth, WiMax, or any form of wireless communication protocol.

In an embodiment, the volatile memory 1032 includes, but is not limited to, Synchronous Dynamic Random Access Memory (SDRAM), Dynamic Random Access Memory (DRAM). RAMBUS Dynamic Random Access Memory (RDRAM), and/or any other type of random access memory device. The non-volatile memory 1034 includes, but is not limited to, flash memory, phase change memory (PCM), read-only memory (ROM), electrically erasable programmable read-only memory (EEPROM), cross-point memory or any other type of non-volatile memory device.

The memory 1030 stores information and instructions to be executed by the processor 1010. In an embodiment, the memory 1030 may also store temporary variables or other intermediate information while the processor 1010 is executing instructions. In the illustrated embodiment, the chipset 1020 connects with processor 1010 via Point-to-Point (PtP or P-P) interfaces 1017 and 1022. Either of these PtP embodiments may be achieved using a TSV pillar and electrical bump in backside recess embodiment as set forth in this disclosure. The chipset 1020 enables the processor 1010 to connect to other elements in a TSV pillar and electrical bump in backside recess embodiment in a system 1000. In an embodiment, interfaces 1017 and 1022 operate in accordance with a PtP communication protocol such as the Intel® QuickPath Interconnect (QPI) or the like. In other embodiments, a different interconnect may be used.

In an embodiment, the chipset 1020 is operable to communicate with the processor 1010, 1005N, the display device 1040, and other devices 1072, 1076, 1074, 1060, 1062, 1064, 1066, 1077, etc. The chipset 1020 may also be coupled to a wireless antenna 1078 to communicate with any device configured to at least do one of transmit and receive wireless signals.

The chipset 1020 connects to the display device 1040 via the interface 1026. The display 1040 may be, for example, a liquid crystal display (LCD), a plasma display, cathode ray tube (CRT) display, or any other form of visual display device. In an embodiment, the processor 1010 and the chipset 1020 are merged into a TSV pillar and electrical bump in backside recess embodiment in a system. Additionally, the chipset 1020 connects to one or more buses 1050 and 1055 that interconnect various elements 1074, 1060, 1062, 1064, and 1066. Buses 1050 and 1055 may be interconnected together via a bus bridge 1072 such as at least one TSV pillar and electrical bump in backside recess embodiment. In an embodiment, the chipset 1020, via interface 1024, couples with a non-volatile memory 1060, a mass storage device(s) 1062, a keyboard/mouse 1064, a network interface 1066, smart TV 1076, and the consumer electronics 1077, etc.

In an embodiment, the mass storage device 1062 includes, but is not limited to, a solid state drive, a hard disk drive, a universal serial bus flash memory drive, or any other form of computer data storage medium. In one embodiment, the network interface 1066 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 10 are depicted as separate blocks within the TSV pillar and electrical bump in backside recess embodiments in a computing system 1000, the functions performed by some of these blocks may be integrated within a single semiconductor circuit or may be implemented using two or more separate integrated circuits. For example, although cache memory 1016 is depicted as a separate block within processor 1010, cache memory 1016 (or selected aspects of 1016) can be incorporated into the processor core 1012. To illustrate the TSV pillar and electrical bump in backside recess embodiments and methods disclosed herein, a non-limiting list of examples is provided herein:

Example 1 is a semiconductive die, comprising: a semiconductive device substrate including an active surface and a backside surface; a through-silicon via (TSV) pillar that communicates from the active surface to the backside surface; and a recess in the semiconductive device substrate at the backside surface, wherein the TSV pillar emerges within the recess.

In Example 2, the subject matter of Example 1 optionally includes an electrical bump seated in the recess and in contact with the TSV pillar.

In Example 3, the subject matter of any one or more of Examples 1-2 optionally include an electrical bump seated in the recess and in contact with the TSV pillar; and a semiconductor package substrate in contact with the electrical bump.

In Example 4, the subject matter of any one or more of Examples 1-3 optionally include an electrical bump seated in the recess and in contact with the TSV pillar; and a package substrate in contact with the electrical bump, and wherein the TSV pillar also contacts the package substrate.

In Example 5, the subject matter of any one or more of Examples 1-4 optionally include wherein the semiconductive device substrate is a first die, further including: a first electrical bump seated in the recess and in contact with the TSV pillar; a package substrate in contact with the first electrical bump; and a subsequent die in contact with the active surface by a subsequent electrical bump.

In Example 6, the subject matter of any one or more of Examples 1-5 optionally include wherein the semiconductive device substrate is a first die, further including: an electrical bump seated in the recess and in contact with the TSV pillar; a semiconductor package substrate in contact with the electrical bump; and a contact pillar that contacts the active surface and a subsequent die.

In Example 7, the subject matter of any one or more of Examples 1-6 optionally include wherein the semiconductive device substrate is a first die, further including: a first electrical bump seated in the recess and in contact with the TSV pillar; a subsequent die in contact with the first electrical bump; and a second electrical bump in contact with active surface.

In Example 8, the subject matter of Example 7 optionally includes wherein the TSV pillar also contacts the subsequent die.

In Example 9, the subject matter of any one or more of Examples 1-8 optionally include wherein the semiconductive device substrate is a first die, further including: a first electrical bump seated in the recess and in contact with the TSV pillar; a subsequent die in contact with the first electrical bump; a second electrical bump in contact with active surface; and a semiconductor package substrate that contacts the second electrical bump.

In Example 10, the subject matter of any one or more of Examples 1-9 optionally include wherein the semiconductive device substrate is a first die, and wherein the TSV pillar is a first TSV pillar, and wherein the recess is a first recess, further including: a first electrical bump seated in the first recess and in contact with the first TSV pillar; a subsequent die in contact with the first electrical bump; a second TSV pillar that communicates from the active surface to the backside surface; a second recess in the first die at the backside surface, wherein the second TSV pillar emerges within the second recess; and a second electrical bump that contacts the second TSV pillar and a second die.

In Example 11, the subject matter of any one or more of Examples 1-10 optionally include wherein the semiconductive device substrate is a first die, and wherein the TSV pillar is a first TSV pillar, and wherein the recess is a first recess, further including: a first electrical bump seated in the first recess and in contact with the first TSV pillar; a subsequent die in contact with the first electrical bump; a second TSV pillar that communicates from the active surface to the backside surface; a second recess in the first die at the backside surface, wherein the second TSV pillar emerges within the second recess; a second electrical bump that contacts the second TSV pillar and a second die; and a package substrate electrical bump that contacts the active surface and a semiconductor package substrate.

In Example 12, the subject matter of any one or more of Examples 1-11 optionally include wherein the semiconductive device substrate is a first die, and wherein the TSV pillar is a first TSV pillar, further including: a first electrical bump seated in the recess and in contact with the first TSV pillar; a subsequent die in contact with the first electrical bump; a second TSV pillar that communicates from the active surface to the backside surface; a second recess in the first die at the backside surface, wherein the second TSV pillar emerges within the second recess; a second electrical bump in contact with the second TSV pillar; a second die in contact with the second electrical bump; and a contact pillar that contacts the active surface and a semiconductor package substrate.

In Example 13, the subject matter of any one or more of Examples 1-12 optionally include wherein the semiconductive device substrate is a first die, and wherein the TSV pillar is a first TSV pillar, further including: a first electrical bump seated in the recess and in contact with the first TSV pillar; a subsequent die in contact with the first electrical bump; a second TSV pillar that communicates from the active surface to the backside surface; a second recess in the first die at the backside surface, wherein the second TSV pillar emerges within the second recess; a second electrical bump in contact with the second TSV pillar; a second die in contact with the second electrical bump; and a package substrate electrical bump that contacts the active surface and a semiconductor package substrate.

In Example 14, the subject matter of Example 13 optionally includes a third semiconductive device coupled to the first die through a third TSV pillar and a third electrical bump.

Example 15 is a process of forming a semiconductor apparatus, comprising: thinning a semiconductive device substrate at a backside surface to expose a through-silicon via (TSV) post; and removing semiconductive material at the backside surface adjacent the post to form a recess and to further expose the TSV post.

In Example 16, the subject matter of Example 15 optionally includes wherein thinning includes isotropic etching the backside surface under conditions selective to leaving the TSV post.

In Example 17, the subject matter of any one or more of Examples 15-16 optionally include wherein removing includes directional etching the backside surface by using a mask.

In Example 18, the subject matter of any one or more of Examples 15-17 optionally include forming an electrical bump on the TSV post under conditions to seat the electrical bump in the recess.

In Example 19, the subject matter of Example 18 optionally includes wherein forming the electrical bump includes contacting the TSV post with molten solder under conditions to adhere the molten solder to the TSV post and to substantially fill the recess.

In Example 20, the subject matter of any one or more of Examples 18-19 optionally include contacting the electrical bump to a subsequent semiconductive device.

In Example 21, the subject matter of any one or more of Examples 18-20 optionally include contacting the electrical bump to a semiconductor package substrate.

Example 22 is a computing system, comprising: a semiconductive device substrate including an active surface and a backside surface; a through-silicon via (TSV) pillar that communicates from the active surface to the backside surface; a recess in the semiconductive device substrate at the backside surface, wherein the TSV pillar emerges within the recess; an electrical bump seated in the recess and in contact with the TSV pillar; wherein the electrical bump contacts one selected from the group consisting of a semiconductor package substrate and a subsequent semiconductive device; and wherein the semiconductive device substrate is part of a chipset.

In Example 23, the subject matter of Example 22 optionally includes wherein the semiconductive device substrate is coupled to the semiconductor package substrate, further including wherein the semiconductor package substrate is coupled to a board, and wherein the board includes a shell that provides electrical insulation for the semiconductive device substrate.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described.

However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electrical device to perform methods as described in the above examples. An implementation of such methods can include code, such as microcode, assembly language code, a higher-level language code, or the like.

Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the disclosed embodiments should be determined with reference to the appended claims, along with the full scope of equivalents to which such claims are entitled.

1. A semiconductive die, comprising:
a semiconductive device substrate including an active surface and a backside surface;
a through-silicon via (TSV) pillar that communicates from the active surface to the backside surface; and
a recess in the semiconductive device substrate at the backside surface, wherein the TSV pillar emerges within the recess.

2. The semiconductive die of claim 1, further including an electrical bump seated in the recess and in contact with the TSV pillar.

3. The semiconductive die of claim 1, further including:
an electrical bump seated in the recess and in contact with the TSV pillar; and
a semiconductor package substrate in contact with the electrical bump.

4. The semiconductive die of claim 1, further including:
an electrical bump seated in the recess and in contact with the TSV pillar; and
a package substrate in contact with the electrical bump, and wherein the TSV pillar also contacts the package substrate.

5. The semiconductive die of claim 1, wherein the semiconductive device substrate is a first die, further including:
a first electrical bump seated in the recess and in contact with the TSV pillar;
a package substrate in contact with the first electrical bump; and
a subsequent die in contact with the active surface by a subsequent electrical bump.

6. The semiconductive die of claim 1, wherein the semiconductive device substrate is a first die, further including:
an electrical bump seated in the recess and in contact with the TSV pillar;
a semiconductor package substrate in contact with the electrical bump; and
a contact pillar that contacts the active surface and a subsequent die.

7. The semiconductive die of claim 1, wherein the semiconductive device substrate is a first die, further including:
a first electrical bump seated in the recess and in contact with the TSV pillar;
a subsequent die in contact with the first electrical bump; and
a second electrical bump in contact with active surface.

8. The semiconductive die of claim 7, wherein the TSV pillar also contacts the subsequent die.

9. The semiconductive die of claim 1, wherein the semiconductive device substrate is a first die, further including:
a first electrical bump seated in the recess and in contact with the TSV pillar;
a subsequent die in contact with the first electrical bump;
a second electrical bump in contact with active surface; and
a semiconductor package substrate that contacts the second electrical bump.

10. The semiconductive die of claim 1, wherein the semiconductive device substrate is a first die, and wherein the TSV pillar is a first TSV pillar, and wherein the recess is a first recess, further including:
a first electrical bump seated in the first recess and in contact with the first TSV pillar;
a subsequent die in contact with the first electrical bump;
a second TSV pillar that communicates from the active surface to the backside surface;
a second recess in the first die at the backside surface, wherein the second TSV pillar emerges within the second recess; and
a second electrical bump that contacts the second TSV pillar and a second die.

11. The semiconductive die of claim 1, wherein the semiconductive device substrate is a first die, and wherein the TSV pillar is a first TSV pillar, and wherein the recess is a first recess, further including:
a first electrical bump seated in the first recess and in contact with the first TSV pillar;
a subsequent die in contact with the first electrical bump;
a second TSV pillar that communicates from the active surface to the backside surface;
a second recess in the first die at the backside surface, wherein the second TSV pillar emerges within the second recess;
a second electrical bump that contacts the second TSV pillar and a second die; and
a package substrate electrical bump that contacts the active surface and a semiconductor package substrate.

12. The semiconductive die of claim 1, wherein the semiconductive device substrate is a first die, and wherein the TSV pillar is a first TSV pillar, further including:
a first electrical bump seated in the recess and in contact with the first TSV pillar;
a subsequent die in contact with the first electrical bump;
a second TSV pillar that communicates from the active surface to the backside surface;
a second recess in the first die at the backside surface, wherein the second TSV pillar emerges within the second recess;
a second electrical bump in contact with the second TSV pillar;
a second die in contact with the second electrical bump; and
a contact pillar that contacts the active surface and a semiconductor package substrate.

13. The semiconductive die of claim 1, wherein the semiconductive device substrate is a first die, and wherein the TSV pillar is a first TSV pillar, further including:
a first electrical bump seated in the recess and in contact with the first TSV pillar;
a subsequent die in contact with the first electrical bump;
a second TSV pillar that communicates from the active surface to the backside surface;
a second recess in the first die at the backside surface, wherein the second TSV pillar emerges within the second recess;
a second electrical bump in contact with the second TSV pillar;
a second die in contact with the second electrical bump; and
a package substrate electrical bump that contacts the active surface and a semiconductor package substrate.

14. The semiconductive die of claim 13, further including:
a third semiconductive device coupled to the first die through a third TSV pillar and a third electrical bump.

15. A process of forming a semiconductor apparatus, comprising:
thinning a semiconductive device substrate at a backside surface to expose a through-silicon via (TSV) post; and
removing semiconductive material at the backside surface adjacent the post to form a recess and to further expose the TSV post.

16. The process of claim 15, wherein thinning includes isotropic etching the backside surface under conditions selective to leaving the TSV post.

17. The process of claim 15, wherein removing includes directional etching the backside surface by using a mask.

18. The process of claim 15, further including forming an electrical bump on the TSV post under conditions to seat the electrical bump in the recess.

19. The process of claim 18, wherein forming the electrical bump includes contacting the TSV post with molten solder under conditions to adhere the molten solder to the TSV post and to substantially fill the recess.

20. The process of claim 18, further including contacting the electrical bump to a subsequent semiconductive device.

21. The process of claim 18, further including contacting the electrical bump to a semiconductor package substrate.

22. A computing system, comprising:
a semiconductive device substrate including an active surface and a backside surface;
a through-silicon via (TSV) pillar that communicates from the active surface to the backside surface;
a recess in the semiconductive device substrate at the backside surface, wherein the TSV pillar emerges within the recess;
an electrical bump seated in the recess and in contact with the TSV pillar;
wherein the electrical bump contacts one selected from the group consisting of a semiconductor package substrate and a subsequent semiconductive device; and
wherein the semiconductive device substrate is part of a chipset.

23. The computing system of claim 22, wherein the semiconductive device substrate is coupled to the semiconductor package substrate, further including wherein the semiconductor package substrate is coupled to a board, and wherein the board includes a shell that provides electrical insulation for the semiconductive device substrate.
